(19) United States
(12) Patent Application Publication
(10) Pub. No.: US 2009/0224274 A1
(43) Pub. Date: Sep. 10, 2009

(54) TUNING THE EMISSION COLOR OF SINGLE LAYER, PATTERNED FULL COLOR ORGANIC LIGHT EMITTING DIODES

(76) Inventors: Panagiotis Argitis, Agia Paraskevi Attikis (GR); Georgios Pistolis, Agia Paraskevi Attikis (GR)

Correspondence Address: MATHEWS, SHEPHERD, MCKAY, & BRUNEAU, P.A., 29 THANET ROAD, SUITE 201, PRINCETON, NJ, 08540, US

(21) Appl. No.: 12/305,221

(22) PCT Filed: Jun. 19, 2007
(86) PCT No.: PCT/GR2007/000035

§ 371 Date: Dec. 17, 2008

(30) Foreign Application Priority Data
Jun. 19, 2006 (GR) 20060100359

(51) Int. Cl. H01L 33/00; H01L 21/00; C09K 11/02

(52) U.S. Cl. 257/98; 438/29; 252/301.35; 257/E21.001; 257/E33.061

(57) ABSTRACT

A process is provided for the effective tuning of the emitting light of OLEDs and thus, achieving single layer, patterned full color displays of optimal quality. The present invention describes a process for the tuning of the emitting color of OLEDs where in the emissive layer of single layer OLEDs suitable emitters in suitable quantities have been dispersed along with a suitable photoacid generator, thus enabling the photochemical transformation of selected areas of the emissive layer in such a way as to change the spectrum of the emitted light at wish.

### FIELD OF THE INVENTION

One aspect of the invention relates to the tuning of the emission color of Organic Light Emitting Diodes through photochemical transformations with the purpose of achieving single emissive layer, patterned full color displays and relevant lighting devices. The invention also resides in a novel Organic Light Emitting Diode, a light-emitting layer therefor and methods of making the same.

### PRIOR ART

Organic Light Emitting Diodes (hereinafter referred to as OLEDs), have been the subject of intense scientific and technological investigation since their introduction more than a decade ago^{[1,2,3]} A lot of progress has already been achieved but further technological developments are needed for their implementation to be successful in application areas such as displays and lighting, where the effective tuning of the emission color is of great importance.

For instance, the generation of a full-color image in a display requires the existence of nearby discrete areas (also referred to herein as pixels), which are capable of emitting one of the three primary colors, Red, Green, and Blue (R-G-B). So far, several techniques have appeared in the art for producing the three colors needed in the different pixels. In general, the manufacture of a full-color display involves the formation of multi-layer OLED structures^{[4]} and requires deposition and patterning of different polymeric or small organic molecule based layers one over the other, where each one is capable of emitting one of the three-main colors. This process is rather complicated and costly (among others, it requires larger quantities of materials, additional equipment and more lengthy processing) and very often additional problems from intermixing the successive layers cannot be avoided. The deposition and patterning of each individual layer involves quite a few processing steps, which means that there are risks for performance degradation of the pre-existing layer during the deposition and patterning of the new layer.

A different technique for formation of full color displays involves ink jet deposition. However, this technique has limitations to the size of the pixels that can be formed, whereas it is desirable to achieve very small sized pixels for better color spectrum control.

Similar problems are encountered in technologies applied for emission of white light using OLEDs, which have potential for use in the next generation of sources for solid state lighting. White light emission has been reported to be obtained from either multi-layered or also from single layer polymer blends^{[5]} or from all-phosphor-doped devices^{[6}], while recently a blue fluorescent along with green and red phosphorescent doped device has been reported.[⁷] However, in the above case of single layer polymer blends reported there is the disadvantage that the light thus emitted cannot be controlled at wish, as its spectrum is determined by the original composition of the organic material, and in certain cases can be undesirably altered during use; for instance, color degradation due to aging of the blue emitters has been reported.

On the other hand, the effective tuning of the emitting color of OLEDs is vital in order to achieve single layer, patterned full color displays with applications on devices using screens of all kinds, i.e. portable phones and similar devices, PC or TV screens, or on lighting devices.

It is the purpose of the present invention to provide a process for the effective tuning of the light emitted by OLEDs and thus, achieve single layer, patterned full color displays of optimal quality.

### SUMMARY OF THE INVENTION

One aspect of the present invention describes a process for the tuning of the emitting color of OLEDs wherein suitable emitters in suitable quantities have been dispersed in the emissive layer of single layer OLEDs along with a suitable photoacid generator, thus enabling the photochemical transformation of selected areas of the emissive layer in such a way as to change the spectrum of the light emitted.

Advantageously, the process disclosed herein enables the tuning of the color emitted by selected areas to Red, Green and Blue (R-G-B) or to other colors, including but not limited to white color, with suitable conditions, namely with suitable material composition of the emissive layer and/or with suitable exposure dose and/or with suitable exposure wavelength.

Areas emitting the three primary colors, Red-Green-Blue (R-G-B), may be defined in a single layer of a commonly used widegap conducting polymer, poly(9-vinylcarbazole) (PVK) using a suitable green emitter 1-[4-(dimethylamino)phenyl]-6-phenylhexa-1,3,5,-triene (DMA-DPH) along with the red emitter 4-dimethylamino-4′-nitrostilbene (DANS). The selected emitters may be dispersed in the PVK films in the presence of a photoacid generator and the emission may be tuned through photochemical transformations of the probes (or emitters). In particular, the proton induced bleaching of the red probe and the proton induced emission shift of the green one, allows the definition of the three primary color emitting areas.

According to a second aspect of the invention there is provided a method of producing a light-emitting layer for use in an OLED, comprising the steps of:
dispersing at least one light emitter in a semi-conducting polymer, and
altering the light emission spectrum of the or at least one of the light emitters in at least a first part of the light-emitting layer.

According to a third aspect of the invention there is provided a method of producing an OLED, comprising forming on a substrate a layer structure comprising a semi-conducting layer and a light-emitting layer, said layers sandwiched between respective layers of oppositely-charged (in use) electrodes;
wherein the light-emitting layer is produced according to the second aspect of the invention.

According to a fourth aspect of the invention there is provided a light-emitting layer for incorporation into an OLED, said light-emitting layer comprising a conductive polymer in which is dispersed at least one light emitter, wherein in at least a first part of the light-emitting layer the light emission spectrum of the or at least one of the light emitters has been altered in situ.

According to a fifth aspect of the invention, there is provided an OLED comprising a light-emitting layer according to the fourth aspect of the invention.

### DESCRIPTION OF THE DRAWINGS

The present invention will now be described by way of example only and with reference to the following figures.

FIG. 1 (a) illustrates the photochemical transformations of both emitters, the DMA-DPH and the DANS.

FIG. 1 (b) illustrates the color patterning process, where it is shown that the unexposed areas remain red, the areas exposed with the intermediate dose become green and the fully exposed areas emit blue color.

FIG. 2 (a) illustrates a successful experiment of DMA-DPH emission tuning through photochemical transformation inside the conductive PVK matrix.

FIG. 2 (b) is a photograph illustrating the successful color patterning achieved by the process of the present invention.

FIG. 3 illustrates the overlap of PVK's emission and DCM's absorption spectrum.

FIG. 4 illustrate the comparison of photochemically induced changes in the absorption spectrum of DCM dispersed in a poly(methyl methacrylate) (PMMA) matrix in absence and in the presence of PAG. More particularly, FIG. 4a shows 4% w/w DCM, and, FIG. 4b shows 4% w/w DCM and 8% PAG, in PMMA films.

FIG. 5a illustrates the efficient energy transfer from PVK to the DCM emitter (unexposed film containing 4% w/w DCM and 8% w/w PAG) and quenching of probe's emission after exposure (for 1500 and 2500 sec) and

FIG. 5b illustrates the undesirable fluorescence quenching after exposure through filter (for 500, 1500 and 2500 sec) of 100 nm thick films of PVK containing DCM, DPH (at concentrations 2% and 2% w/w) and PAG (8% w/w).

FIG. 6 illustrates energy transfer from PVK to DANS emitter at concentration 2% w/w and fluorescence quenching after exposure (through 248 nm filter) for 1500 sec in the presence of the PAG (at concentration 4% w/w).

FIG. 7a illustrates PL spectra of a PVK film containing DANS, DPH (each probe at concentration 2% w/w of polymer mass, giving a molar ratio of 1:1) and PAG (8% w/w), before (RED color) and after exposure for 1000 sec through 248 nm filter (excitation at 340 nm) (BLUE color), and FIG. 7b illustrates UV absorption spectra of DMA-DPH (parent and protonated) and DANS (parent and protonated). Both emitters were inserted in a PMMA matrix, whose emission at the wavelengths of our interest is near to zero, in concentration 4% in the presence of PAG in concentration 8%. The inserted chart in FIG. 7b corresponds to PVK fluorescence intensity after excitation at 340 nm. All film thicknesses were measured about 100 nm.

FIG. 8a illustrates normalised EL spectra and FIG. 8b illustrates I-V plots of diodes having the structure ITO/PEDOT-PSS 40 nm/active layer 100 nm thick/Al 300 nm. The active layer was either PVK containing 2% w/w DMA-DPH, 1% w/w DANS and 4% w/w PAG unexposed (RED pixel) or exposed through filter for 500 sec (GREEN pixel) and 1500 sec (BLUE pixel).

FIGS. 8c and 8d illustrate fluorescence patterns on the single PVK layer. Red lines (unexposed)—Green lines (exposed through filter for 1000 sec)—Blue lines (exposed 2000 sec) (Film thickness: 100 nm). Lines width: 25 μm.

FIG. 9 illustrates PL spectra of a PVK film containing DANS, DPH (at concentration 4% w/w and 1.5% w/w of polymer mass respectively, which means at a molar ratio about 3:1) and PAG (8% w/w), before (RED color) and after exposure for 1500 sec through 248 nm filter (WHITE color).

### DETAILED DESCRIPTION OF THE INVENTION

This embodiment of the present invention describes a new patterning method for functional thin films. In particular, photochemically induced emission tuning (PIET) is demonstrated for the definition of different color emitting areas in a conducting polymeric layer, in order to define the three primary color emitting pixels (R-G-B) in the same polymeric layer, and thus to simplify full color device fabrication.

The present invention is differentiated from previous work^{[8]}, where a photoacid generation approach was used for emission tuning in polymeric films, but in which the films lacked the properties necessary for emissive layers used in OLEDs. In particular, the strategy proposed previously^{[8,9}] was restricted to bicolor imaging and could not provide photopatterning schemes for the definition of red, green and blue (R-G-B) areas which are necessary for full color displays. Further, in that previous work emission was made through photoluminescence and not through electroluminesence, as used in OLEDs.

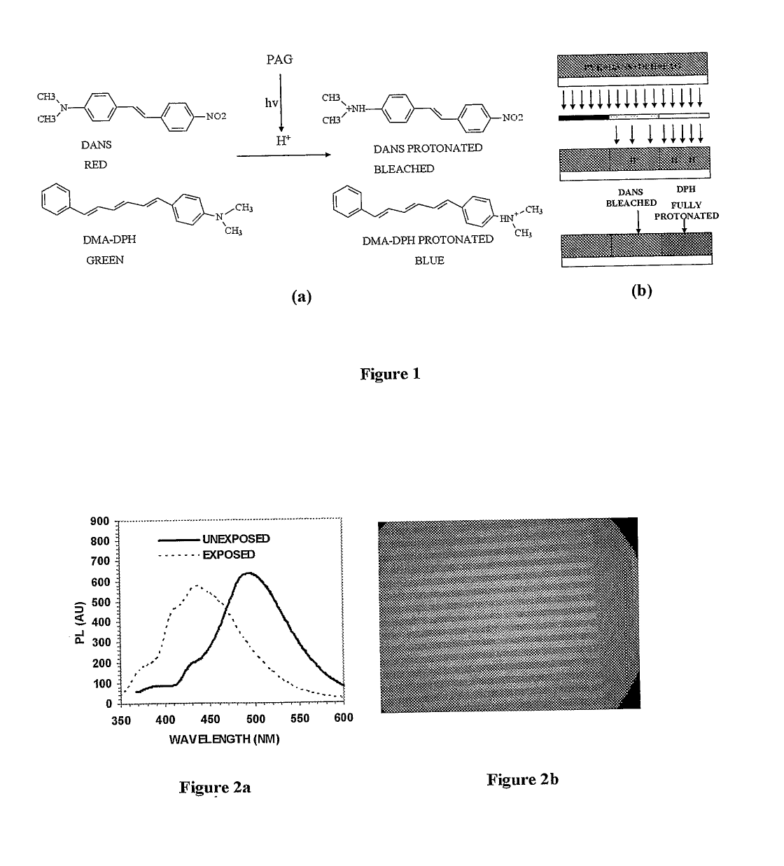

In this embodiment of the present invention, a known blue-emitting, commercially available vinyl polymer, poly(9-vinylcarbazole) (PVK),^{[10]} was mainly used as the host matrix for the fabrication of single layer, full-color emitting OLED-based displays. PVK possesses high energy levels (its emission peak is in the violet-blue region) and it is known for efficient energy transfer to fluorescent and phosphorescent organic molecules with lower energy excited states. In the preferred embodiment of the present invention, the three primary colors emitting areas in a single layer of PVK film were defined using a suitable green emitter 1-[4-(dimethylamino)phenyl]-6-phenylhexa-1,3,5,-triene (DMA-DPH) along with the red emitter (4-dimethylamino-4′-nitrostilbene), (DANS) (FIG. 1 (a)). The selected emitters (also referred to herein as probes) were dispersed in the PVK films in the presence of a photoacid generator (PAG) (the photoacid generator (PAG) used was triphenylsulfonium hexafluoroantimonate, Ph₃S—SbF₆), and the emission was tuned through photochemical transformations of the probes (as shown in FIG. 1 (a)). In particular, through proton induced bleaching of the red probe and proton induced spectral shift of the green one, the definition of the three primary color emitting areas was possible (FIG. 1 (b)).

In a first step towards establishing the process of the invention we examined if it is possible to define two different color areas, in particular Green and Blue, in the same PVK layer through energy transfer from polymeric host to the specific probe (DMA-DPH) and subsequent protonation.

Indeed, as shown in FIG. 2 (a) a successful experiment of DMA-DPH emission tuning through photochemical transformation inside the conductive PVK matrix was performed. From the curve named “unexposed” we can conclude that very efficient energy transfer takes place from the host polymer to the emitter. According to our results, a small concentration of the probe in the matrix (for example 2% of polymer mass), in the presence of the PAG, (e.g. triphenylsulfonium triflate (SPh₃⁺CF₃SO₃⁻)), in a concentration 4% of polymer mass, can lead to the total elimination of the PVK's emission (maximum at 413 nm) and to the appearance of probe's characteristic spectrum (maximum at approximately 500 nm). Emitter concentrations of 1-5% gave the optimal results. However, it is possible to obtain the desired effect even with concentrations of up to 10%, but with a weaker fluorescence signal.

After exposure at 248 nm wavelength region, where only the PAG absorbs strongly, (see FIG. 2(a), curve named “exposed”) the photogenerated acid indeed protonates the dimethylamino group in DMA-DPH, since a 60 nm hypsochromic shift is observed between the unexposed (maximum at 500 nm at green area) and the exposed (maximum at 440 nm at blue area) film. In this way we were able to define two of the three primary colors (R-B) in a single conductive layer of PVK.

The present invention also achieved successful color patterning, as is illustrated in the photograph presented at FIG. 2 (b). The exposure of PVK films containing the DMA-DPH emitter and the PAG through a photolithographic mask results in the generation of acid in selected film areas according to a well-established microlithographic process. The fluorescence probe is dispersed in the polymeric film and the photoacid generation leads to the definition of distinct color lines, blue and green, in the polymeric film.

In the next step and in order to define all three primary colors, (R-G-B), in a single layer of PVK we inserted a red emitting dye in PVK matrix along with the green emitter DMA-DPH and the PAG. Initially, emission is expected only from the lower bandgap compound, which emits red color. By means of bleaching the red probe fluorescence through exposure we define a green emitting area since the parent compound of DMA-DPH emits green color. Then, with subsequent irradiation we fully protonated the green emitter and achieved the blue emission of its photochemical product.

Several red emitters were tested, including 4-(dicyanomethylene)-2-methyl-6-[4-(dimethylaminostyryl)-4H-pyran], DCM,[^{11,12}] known in OLEDs technology as a highly fluorescent dopant. In the case of DCM inserted in a PVK matrix, both efficient energy transfer from the host polymer to the emitter and bleaching of its emission after exposure in the presence of PAG, were observed.

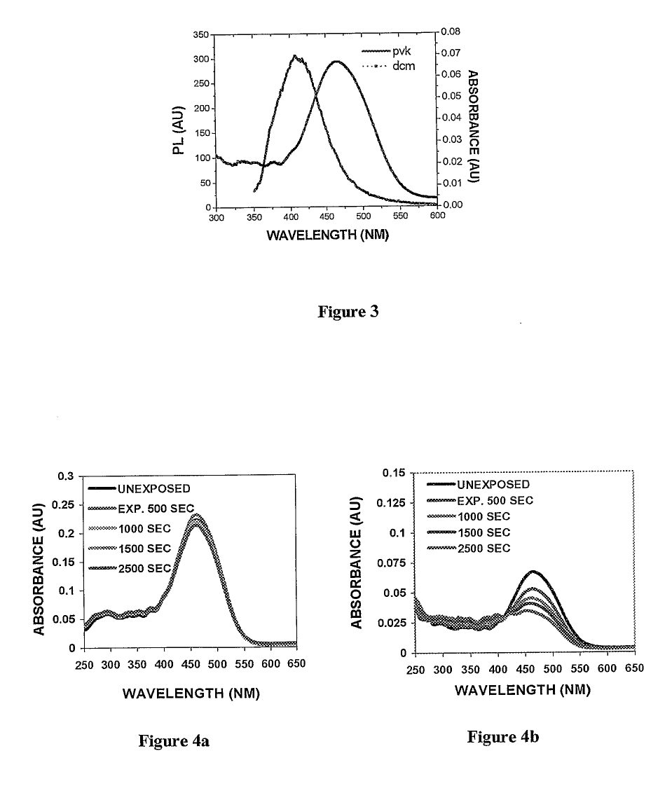

More particularly, initially, in order to examine whether efficient energy transfer from the PVK host polymer to the DCM red emitter can take place, we recorded PVK's PL and DCM's absorption (in inert PMMA matrix) spectra, which are presented in FIG. 3. In these spectra we can observe that there is sufficient overlap of PVK's emission and DCM's absorption and, hence, we expect that the excitation energy can be effectively transferred from the polymer molecules to the probe.

FIG. 3 illustrates the overlap of PVK's emission and DCM's absorption spectrum. The absorption spectrum of DCM was obtained in probe concentration 4% w/w per polymer mass in PMMA matrix, whose absorption at the wavelength range of interest is near to zero.

DCM's stability during exposure was confirmed, as one can see in FIG. 4 (a), where UV absorption spectra of PMMA containing 4% w/w of DCM emitter under exposure through a 248 nm narrow band filter (for 0, 500 sec, 1000 sec, 1500 sec and 2500 sec respectively in the presented case) are presented. In FIG. 4 (b) corresponding spectra of PMMA containing 4% w/w DCM and 8% w/w photoacid generator are shown. In the presence of PAG a decrease of DCM's absorption at the 460 nm wavelength area after exposure was observed, evidence for protonation during exposure.

For the comparison of photochemically induced changes in the absorption spectrum of DCM dispersed in PMMA matrix in absence and in the presence of PAG, (FIG. 4a) 4% w/w DCM, and, (FIG. 4b) 4% w/w DCM and 8% PAG, in PMMA films, the spectra were taken after exposure through 248 nm narrow band filter for 0, 500 sec, 1000 sec, 1500 sec and 2500 sec.

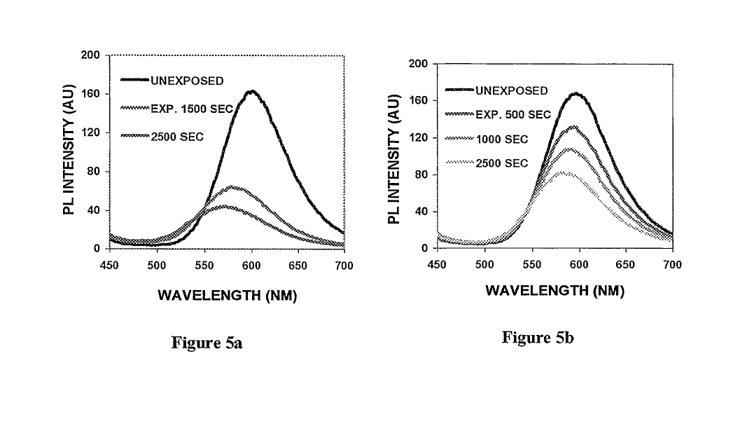

Next, PL spectra of PVK containing DCM (4% w/w) and PAG (8% w/w) were recorded, in order to examine if energy transfer and desirable quenching of probe's emission after exposure, could be observed. Indeed, from FIG. 5 (a) it is evident that efficient energy transfer from PVK host to DCM emitter has taken place, since the emission maximum of unexposed film is at about 605 nm, while pure PVK emits at blue-violet wavelength region, with a maximum at 413 nm. In addition, the desirable bleaching after exposure for increased dose (0 sec, 1500 sec, 2500 sec) was confirmed, as one can also see in FIG. 5 (a).

In FIG. 5 b PL spectra of DCM (2% w/w) and DPH (2% w/w) in PVK matrix, before and after exposure through filter for 500, 1500 and 2500 sec in the presence of PAG (8% w/w), are shown. Unfortunately, undesirable bleaching of the total emission, rather than blue shift, was observed after exposure, which was confirmed in every case where DCM was inserted (even at small amounts) in PVK containing DPH dye and PAG. For this reason other red emitting probes were tested in order to find those suitable for use in this embodiment of the invention.

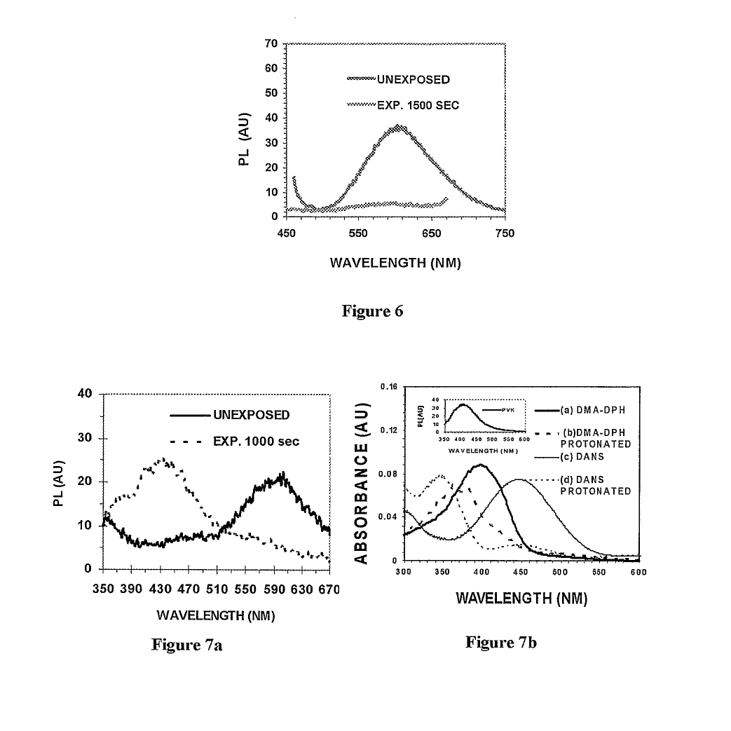

After several experiments 4-dimethylamino-4′-nitrostilbene (DANS)[¹³], a known red probe (especially in the field of monitoring polymerization processes in real time), was chosen. Efficient energy transfer from PVK to the DANS emitter (maximum at 605 nm) and bleaching of its emission after exposure in the presence of PAG, was initially confirmed, as seen in FIG. 6a, where PL spectra of unexposed PVK film containing the DANS emitter and a PAG at concentrations of 2 and 8% w/w since the maximum is at 605 nm.

FIG. 6a illustrates the energy transfer from PVK to the DANS emitter at concentration of 2% w/w, and fluorescence quenching after exposure (through 248 um filter) for 1500 sec in the presence of the PAG (at a concentration of 4% w/w).

In the next step we introduced the DANS along with the DPH emitter (in a molecular ratio of 1:1) and the PAG in a PVK matrix, and the red fluorescence of DANS was observed in the unexposed film. After exposure, a 165 nm shift to shorter wavelengths (maximum at 440 nm), corresponding to blue fluorescence of DPH protonated molecule, was observed, as we shown in FIG. 7a. It can be seen that, during exposure, bleaching of red emitter and protonation of the green emitter took place and thus we achieved the blue emission of its photochemical product. In this way R-B emitting areas were photopatterned in the same layer of PVK.

In this point it is crucial to discuss further this photochemically induced emission tuning of PVK containing the emitters and the PAG presented above. PVK is a large bandgap conductive polymer, emitting in the violet-blue area (from about 350 nm to 470 nm, peak at 413 nm) of the optical spectrum (see FIG. 7b, inserted curve). On the other hand, the DPH and DANS starting forms both absorb in this same wavelength area. In particular, DPH has an absorption maximum at 390 nm and DANS absorbs strongly at about 440 nm (see FIG. 7b, curves (a) and (c) respectively. It is clear that the efficient energy transfer from PVK host to both emitters is due to the large degree of overlap of its emission with their absorption (especially in the case of DPH this degree of overlap is almost 100%). For this reason, in the case of PVK containing both probes, the lower bandgap product, i.e. the red emitting DANS, is expected to fluoresce after excitation. After exposure, the DANS absorption spectrum shifts to the blue and has a maximum at 340 nm (curve d) and thus no longer overlaps with the PVK emission spectrum. On the other hand, the DPH protonated form, obtained after exposure, has an absorption spectrum (maxima at 360 and 380 nm, curve b), which still overlaps with PVK emission. For the above reason only the DPH starting form (if the degree of protonation is low) or the protonated form (in the case where the protonation is almost complete) can emit. In other words, after exposure (and the bleaching of the red probe fluorescence) green or blue emission is expected.

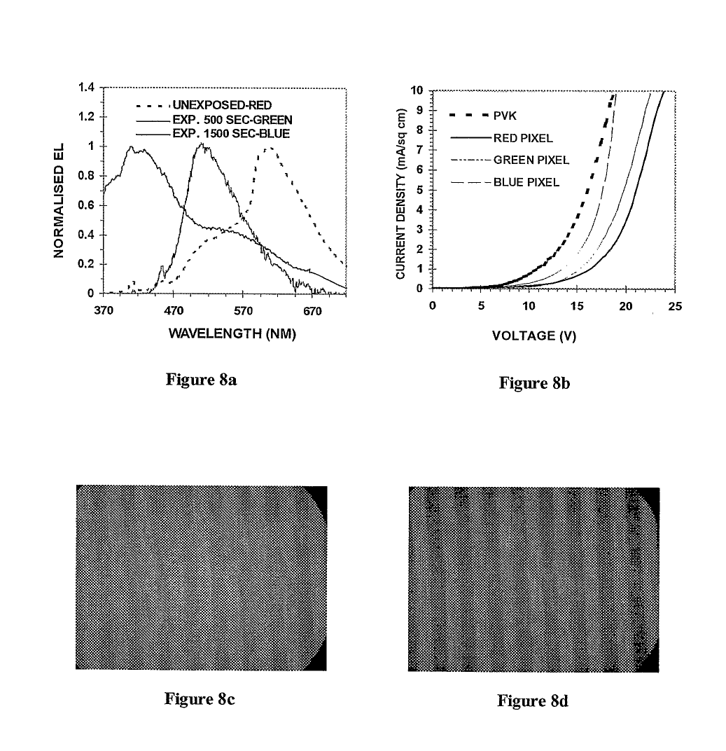

In the experiment presented in FIG. 7a, after exposure of the initial red emitting film only blue emission and not the intermediate green one, was observed. We concluded that this means that the protonation of both probes take place in parallel (as it is expected by the similarity of their protonation sides (i.e. their protonated structures), see FIG. 1) and both are practically fully protonated at the end of the exposure. For this reason, and after preliminary experiments, we decided to insert in the PVK matrix the DPH in a molar ratio at least 2:1 relative to DANS (2% and 1% of the polymer mass respectively). In parallel, we decreased the amount of PAG (to 4% of the polymer mass), in order to facilitate the optimisation of the processing conditions towards effective control of the emission color changes. We believed that when the DANS would be protonated to a degree that would be adequate to bleach its fluorescence the amount of DPH starting (green emitting) form would be still enough to emit green color. At a larger exposure dose the DPH would be almost fully protonated and for this reason only blue emission was expected. Indeed, in FIGS. 8a and 8b we present the normalised EL spectra and I-V plots of the three primary colors emitting pixels, successfully patterned in the same layer of PVK, which is the emitting layer of the OLEDs. Each of the diodes has the structure ITO/PEDOT-PSS 40 nm/emitting layer of PVK (having the emitters DPH and DANS at molar ratio 2:1 and the PAG dispersed in it) 100 nm/Al 300 nm. Each pixel of these diodes corresponding to an unexposed area of PVK films emits red color. Those pixels corresponding to areas exposed at an intermediate dose emit green color and those corresponding to areas exposed at larger doses emit blue color. It should be mentioned that further investigation of probes molar ratio and exposure dose is needed, in order to improve red's and blue's spectral purities respectively.

The addition of the photoacid generator and the probes into the polymer matrix does not significantly affect the electrical behaviour of the diode, as one can see in FIG. 8b. Only a small increase of threshold voltage is observed for diodes having the additives (especially for the red emitting pixels), relative to those based on pure PVK. On the other hand, we had a slight increase of current and decrease of threshold voltage in exposed green and especially blue pixel relative to the red unexposed one. This observation probably indicates an increased current diffusion into the exposed matrix.

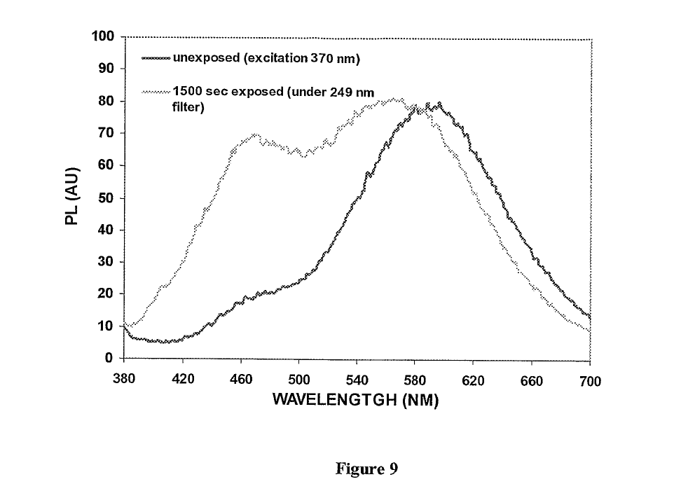

R-G-B color emitting areas of the same photopatterned PVK film are shown in photographs presented as FIGS. 8c and 8d. The exposure of PVK films through a lithographic mask for 1000 sec in our exposure conditions (see experimental details below) resulted in the formation of green emitting areas, while for 2000 sec led to the definition of blue lines. Red lines correspond to unexposed areas. The lines dimensions shown are 25 μm. It should be mentioned that it wasn't possible to achieve the three different emitting color lines together due to the lack of an appropriate grey photolithographic mask. It should also be mentioned that with careful control of the exposure dose and the probes and PAG concentrations it was possible to achieve several different color emitting areas, even white light emission., as it can be seen in FIG. 9, where we present PL spectra of a PVK film containing DANS, DPH (at concentrations 4% w/w and 1.5% w/w of polymer mass respectively, which means at a molar ratio about 3:1) and PAG (8% w/w), before (RED color) and after exposure for 1500 sec through 248 nm filter (WHITE color).

### EXAMPLES

### Example 1

### Preparation of Materials and Processing

Solutions containing PVK (40 mg/ml in 1,1,2,2 tetrachloroethane) and poly(methyl methacrylate) (PMMA) (4% w/w in methylisobutylketone-MIBK) were prepared in order to record probes absorption spectra. In some of them the fluorescence probe DMA-DPH (1%, 2% and 4% of polymer mass) and the PAG in various contents (4%, 6% and 8% of polymer mass) were added. In other polymeric solutions photoacid generator, the DANS emitter at various concentrations (from 1:10 to 10:1 of DPH amount) was also added along with the DMA-DPH. Films were spin coated on quartz substrates in order to record absorption and fluorescence spectra from filtered solutions at 2000 r.p.m. and then baked on a hotplate at 80° C. for 10 min. Film thicknesses were measured with a Dektak profilometer and found to be about 100 nm. Photoacid generation was induced by exposing films with a 500 Watt Oriel Hg—Xe exposure tool through a 248 nm narrowband filter (6.5 nm half band width) for assessed times (see text). The incident power was 0.21±0.02 mJ/s.

### Example 2

### Preparation and Characterization of Electroluminescent Devices

For the electroluminescent devices PVK 100 nm thick films were spun on ITO-coated glass substrates at 2000 rpm and baked at 80° C. for 10 min. ITO-coated glass substrates were precleaned in an ultrasonic bath with a sequence of acetone, isopropanol and DI water and treated with oxygen plasma to improve the ITO properties. Prior the PVK containing the emitters and the pag emissive layer was spin coated a 40 nm thick film of Poly(3,4-ethylene dioxythiophene):poly(styrene sulfonate) (PEDOT-PSS) was also spin coated—at 4000 rpm and baked at 125° C. for 15 min—to improve hole injection and substrate smoothness and enhance the performance of the EL device increased current density. After the emissive layer was deposited (by spin coating) the emission of its selected areas was tuned at wish by exposure to UV irradiation for suitable times. After that Aluminum cathode electrodes 300 nm thick were deposited on top of PVK thin films by vacuum evaporation. All the testing devices have an active area 2×2 mm². Current density-voltage (J-V) measurements were obtained using a programmable Keithley 230 Voltage Source and 195 A Multimeter. Electroluminescence (EL) spectra were recorded using an USB 2000-UV-Vis miniature fiber optic spectrometer.

### REFERENCES

1 J. H. Burroughes, D. D. C. Bradley, A. R. Brown, R. N. Marks, K. Mackay, R. H. Friend, P. L. Burns, A. B. Holmes, Nature 1990, 347, 539.
2 C. W. Tang, S. A. VanSlyke, Appl. Phys. Let. 1987, 51, 913-5.
3(a) D. A. Pardo, G. E. Jabbour, N. Peyghambarian, Adv. Mater. 2000, 12, 1249, (b) B. W. D'Adrade, J. Brooks, V. Adomovich, M. E. Thomson, S. R. Forrest, Adv. Mater. 2002, 14, 1032, (c) M. Pfeiffer, S. R. Forrest, K. Leo, M. E. Thomson, Adv. Mater. 2002, 14, 1633.
4 (a) G. Gu, V. Bolovic, P. E. Burrows, S. R. Forrest, M. E. Thompson, Appl. Phys. Let. 1996, 68(19), 2606-2608, (b) G. Parthasarathy, G. Gu, S. R. Forrest, Adv. Mater 1999, 11, 907, (c) X. Jiang, Z. Zhang, W. Zhao, W. Zhu, B. Zhang, S. Xu, J. Phys. D: Appl. Phys. 2000, 33, 473, (d) B. W. D'Andrade, M. E. Thompson, S. R. Forrest, Adv. Mater. 2002, 14, 147.
5 (a) S. Tasch, E. J. W. List, O. Ekström, W. Graupner, G. Leising, P. Schlichting, U. Rohr, Y. Geerts, U. Scherf, K. Müllen, Appl. Phys. Lett. 1997, 71, 2883, (b) J. Kido, H. Shionoya, K. Nagai, Appl. Phys. Lett. 1995, 67, 2281.
6 (a) B. W. D'Adrade, R. J. Holmes, S. R. Forrest, Adv. Mat. 2004, 16, 624, (b) S. Tokito, T. Iijima, T. Tsuzuki, F. Sato, Appl. Phys. Let. 2003, 83, 2459.
7 Y. Sun, N. C. Giebink, H. Kanno, B. Ma, M. E. Thomson, S. R. Forrest, Nature 2006, 440, 908.
8 G. Pistolis, S. Boyatzis, M. Chatzichristidi, P. Argitis, Chem. Mater. 2002, 14, 790.
9 M. Vasilopoulou, G. Pistolis and P. Argitis, Journal of Physics: Conference Series 2005, 10, 285-288.
10 (a) J. Kido, K. Hongawa, K. Okuyama and K. Nagai Appl. Phys. Lett., 1993, 63, 2627, (b) C-L Lee, R. Ragini Das, J-J Kim, Chem. Mater. 2004, 16, 4642, (c) T. Dantas de Morais, F. Chaput, K. Lahlil, J-P Boilot. Adv. Mater., 1999, 11, 107, (d) Y. H. Niu, B. Q. Chen, T. D. Kim, M. S. Liu, A. K. Y. Jen, Appl. Phys. Let. 2004, 85 (22), 5433-5435, (e) F C Chen, Y Yang, M E Thompson, J Kido Appl. Phys. Lett., 2002, 80, 2308.
11 C. W. Tang, S. A. Van Slyke, C. H. Chen, J. Appl. Phys. 1989, 65, 3610.
12 (a) J. Kido, K. Hongawa, K. Okugama, N. Nagai, Appl. Phys. Lett. 1994, 64, 815. (b) H. Suzuki, S. Hoshino, J Appl. Phys. 1996, 79, 8816. (c) V. Bulovic, A. Shoustikov, M. A. Baldo, E. Bose, V. G. Gozlov, M. E. Thomson, S. R. Forrest, Chem. Phys. Lett. 1998, 287, 455. (d) B.-J. Jung, C.-B. Yoon, H.-K. Shim, L.-M. Do, T. Zyung, Adv. Funct. Mater. 2001, 11, 430. (e) T.-H. Liu, C.-W. Iou, C. H. Chen, Appl. Phys. Lett. 2003, 83, 5241. (f) C.-L. Chiang, M.-F. Wu, D.-C. Dai, W.-S. Wen, J.-K. Wang, C.-T. Chen, Adv. Funct. Mater. 2005, 15, 231.
13 (a) E. Lippert, W. Lüder, F. Moll, W. Nägelle, H. Boos, H. Prigge, Angew. Chem. 1961, 73, 695. (b) A. P. de Silva, H. Q. Nimal Gunaratne, T. Gunnlougsson, A. J. M. Huxley, C. P. McCoy, J. T. Rademacher, T. E. Rice, Chem. Rev. 1997, 97, 1515. (c) J. F. Jager, A. M. Sarker, D. C. Neckers, Macromolecules 1999, 32, 8791. (d) A. M. Moran, G. P. Bartholomew, G. C. Bazan, A. M. Kelley, J. Phys. Chem. A 2002, 106, 4928. (e) T. Nakabayashi, Md. Wahadoszamen, N. Ohta, J. Am. Chem. Soc. 2005, 127, 7041.

1. A method of producing a light-emitting layer for use in an Organic Light-Emitting Diode, comprising:
dispersing at least one light emitter in a semiconducting polymer, and
altering the light emission spectrum of the or at least one of the light emitters in at least a first part of the light-emitting layer.

2. The method of claim 1, wherein the semiconducting polymer comprises an electroluminescent polymer, and the at least one light emitter is fluorescent and/or phosphorescent, such that the electroluminescent polymer is able to transfer energy to the at least one light emitter.

3. The method of claim 2, wherein the electroluminescent polymer comprises poly(9-vinylcarbazole) (PVK).

4. The method of claim 1, wherein the or one of the light emitters is 1-[4-(dimethylamino)phenyl]-6-phenylhexa-1,3,5-triene (DMA-DPH).

5. The method of claim 1, wherein the or one of the light emitters is 4-dimethylamino-4′-nitrostilbene (DANS).

6. The method claim 1, wherein in at least a second part of the light-emitting layer, the light emission spectrum of the or at least one of the light emitters is not altered.

7. The method of claim 1, comprising dispersing two light emitters in the conductive polymer, and altering the light emission spectrum of at least one of the two light emitters in at least the first part of the light-emitting layer.

8. The method of claim 7, comprising altering the light emission spectrum of both of the two light emitters in at least the first part of the light-emitting layer.

9. The method of claim 7, wherein in at least the second part of the light-emitting layer, the light emission spectrum of both of the light emitters is not altered.

10. The method of claim 1, wherein the semiconducting polymer additionally has dispersed therein at least one photoacid generator (PAG), and the alteration of the light emission spectrum of the or at least one of the light emitters is produced by irradiation of the photoacid generator.

11. The method of claim 10, wherein the alteration of the light emission spectrum of the or at least one of the light emitters is caused by protonation of that emitter.

12. The method of claim 10, wherein the photoacid generator comprises triphenylsulfonium hexafluoroantimonate or triphenylsulfonium triflate.

13. The method of claim 11 wherein the or one of the light emitters is 1-[4-(dimethylamino)phenyl]-6-phenylhexa-1,3,5-triene (DMA-DPH) and wherein the or one of the light emitters is 4-dimethylamino-4′-nistilbene (DANS), further comprising defining first, second and third discrete areas of the light-emitting layer for emitting blue-, red- and green-coloured light respectively, and in the first area causing substantially all of both the DMA-DPH and the DANS to be protonated, in the second area causing substantially all of both the DMA-DPH and the DANS to remain unprotonated, and in the third area causing substantially all of the DANS but substantially none, or only a part, of the DMA-DPH to be protonated.

14. A method of producing an Organic Light-Emitting Diode comprising forming on a substrate a layer structure comprising a semiconducting layer and a light-emitting layer, said layers sandwiched between respective layers of oppositely-charged (in use) electrodes;
wherein the light-emitting layer is formed by the method of claim 1.

15. The method of claim 14, wherein the Organic Light Emitting Diode comprises a single light-emitting layer.

16. A light-emitting layer for incorporation into an Organic Light-Emitting Diode, said light-emitting layer comprising a semiconducting polymer in which is dispersed at least one light emitter, wherein in at least a first part of the light-emitting layer the light emission spectrum of the or at least one of the light emitters has been altered in situ.

17. The light-emitting layer of claim 16, wherein the semiconducting polymer comprises an electroluminescent polymer, and the at least one light emitter is fluorescent and/or phosphorescent, such that the electroluminescent polymer is able to transfer energy in use to the at least one light emitter.

18. The light-emitting layer of claim 17, wherein the electroluminescent polymer comprises poly(9-vinylcarbazole) (PVK).

19. The light-emitting layer of claim 16, wherein the or one of the light emitters is 1-[4-(dimethylamino)phenyl]-6-phenymexa-1,3,5-triene (DMA-DPH).

20. The light-emitting layer of claim 16, wherein the or one of the light emitters is 4-dimethylamino-4′-nitrostilbene (DANS).

21. The light-emitting layer of claim 16, wherein in at least a second part of the light-emitting layer, the light emission spectrum of the or at least one of the light emitters has not been so altered.

22. The light-emitting layer of claim 16, wherein within the semiconducting polymer are dispersed two light emitters, and wherein in at least the first part of the light-emitting layer the light emission spectrum of at least one of the two light emitters has been altered in situ.

23. The light-emitting layer of claim 22, wherein in at least the first part of the light-emitting layer, the light emission spectrum of both of the two light emitters has been altered in situ.

24. The light-emitting layer of claim 22, wherein in at least the second part of the light-emitting layer, the light-emission spectrum of both of the light emitters has not been so altered.

25. The light-emitting layer of claim 16, wherein the semiconducting polymer matrix additionally has dispersed therein at least one photoacid generator (PAG), and the alteration of the light emission spectrum of the or at least one of the light emitters was produced by irradiation of the photoacid generator.

26. The light-emitting layer of claim 25, wherein the alteration of the light emission spectrum of the or at least one of the light emitters was caused by protonation of that light emitter.

27. The light-emitting layer of claim 25, wherein the photoacid generator comprises triphenylsulfonium hexafluoroantimonate or triphenylsulfonium triflate.

28. The light-emitting layer of claim 26 wherein the or one of the light emitters is 1-[4-(dimethylamino)phenyl]-6-phenylhexa-1,3,5-triene (DMA-DPH)) and wherein the or one of the light emitters is 4-dimethylamino-4′-nitrostilbene (DANS), wherein the light-emitting layer comprises first, second and third discrete areas emitting blue-, red- and green-coloured light respectively, and wherein in the first area substantially all of both the DMA-DPH and the DANS has been protonated, in the second area substantially all of both the DMA-DPH and the DANS remains unprotonated, and in the third area substantially all of the DANS but substantially none or only a part of the DMA-DPH has been protonated.

29. An Organic Light-Emitting Diode comprising a light-emitting layer according to claim 16.

30. The Organic Light-Emitting Diode of claim 29, wherein the Organic Light-Emitting Diode comprises a single light-emitting layer.

31. A method of tuning the light emission spectrum of predetermined regions within an emissive layer of an Organic Light-Emitting Diode, in which said emissive layer comprises at least one light emitter and a photosensitive reagent which upon exposure to electromagnetic radiation generates a reactant for the at least one light emitter, said method comprising exposing said predetermined regions to electromagnetic radiation of suitable wavelength, thereby causing the or at least one of the light emitters to react with the generated reactant in at least a first part of the emissive layer, and so change the light emission spectrum of the or at least one of the light emitters in at least the first part of the emissive layer.

32. The method of claim 31, wherein the emissive layer further comprises a semiconducting polymer in which the at least one light emitter and photosensitive reagent are dispersed.

33. The method of claim 32, wherein the semiconducting polymer comprises an electroluminescent polymer, and the at least one light emitter is fluorescent and/or phosphorescent, such that the electroluminescent polymer is able to transfer energy in use to the at least one light emitter.

34. The method of claim 33, wherein the electroluminescent polymer comprises poly(9-vinylcarbazole) (PVK).

35. The method of claim 31, wherein the or one of the light emitters is 1-[4-(dimethylamino)phenyl]-6-phenylhexa-1,3,5-triene (DMA-DPH).

36. The method of claim 31, wherein the or one of the light emitters is 4-dimethylamino-4′-nitrostilbene (DANS).

37. The method of claim 31, wherein in at least a second part of the emissive layer, the light emission spectrum of the or at least one of the light emitters is not so changed.

38. The method of claim 31, wherein the emissive layer comprises two light emitters, and exposing said predetermined regions to electromagnetic radiation of suitable wavelength causes at least one of the two light emitters to react with the generated reactant in at least a first part of the emissive layer, and so changes the light emission spectrum of at least one of the light emitters in at least the first part of the emissive layer.

39. The method of claim 38, wherein exposing said predetermined regions to electromagnetic radiation of suitable wavelength causes both of the two light emitters to react with the generated reactant in at least a first part of the emissive layer, and so changes the light emission spectrum of both of the light emitters in at least the first part of the emissive layer.

40. The method of claim 38, wherein in at least the second part of the emissive layer, the light emission spectrum of both of the light emitters is not so changed.

41. The method of claim 31, wherein the photosensitive reagent comprises a photoacid generator.

42. The method of claim 41, wherein the reaction of the or at least one of the light emitters with the generated reactant causes that light emitter or light emitters to be protonated.

43. The method of claim 41, wherein the photoacid generator comprises triphenylsulfonium hexafluoroantimonate or triphenylsulfonium triflate.

44. The method of claim 31, wherein the electromagnetic radiation of suitable wavelength comprises ultraviolet radiation.

45. The method of claim 42 wherein the or one of the light emitters is 1-[4-(dimethylaminophenyl]-6-phenylhexa-1,3,5-triene (DMA-DPH) and wherein the or one of the light emitters is 4-dimethylamino-4′-nitrostilbene (DANS), wherein first, second and third regions are defined corresponding to first, second and third areas for emitting blue, red and green light respectively, and the first region is exposed to a sufficient dose of radiation to cause substantially all of both the DMA-DPH and the DANS to be protonated, the second region is not exposed to any, or to a sufficiently low dose of radiation, so that substantially all of both the DMA-DPH and the DANS remain unprotonated, and the third region is exposed to an intermediate dose of radiation so that substantially all of the DANS but substantially none, or only apart of the DMA-DPH is protonated.
